(19) United States
(12) Patent Application Publication
(10) Pub. No.: US 2008/0124485 A1
(43) Pub. Date: May 29, 2008

(54) METHOD OF SUCCESSIVELY DEPOSITING MULTI-FILM RELEASING PLASMA CHARGE

(75) Inventors: CHAO-SHENG CHIANG, HSINCHU CITY (TW); PING-WEI LIN, HSINCHU CITY (TW); CHIN-WEI YANG, TAICHUNG COUNTY (TW)

Correspondence Address: J C PATENTS, INC., 4 VENTURE, SUITE 250, IRVINE, CA, 92618, US

(73) Assignee: UNITED MICROELECTRONICS CORP., HSINCHU (TW)

(21) Appl. No.: 11/563,568

(22) Filed: Nov. 27, 2006

(51) Int. Cl. C23C 16/513

(52) U.S. Cl. 427/539; 427/535

(57) ABSTRACT

Method of successively depositing a multi-film is disclosed. An electric charge removing process is performed after a deposition process of the last film of the multi-film or between the two neighboring film deposition processes. The electric charge removing process includes introducing an inert gas into a reaction chamber of the deposition system and pumping out the inert gas from the reaction chamber.

### BACKGROUND OF THE INVENTION

1. Field of the Invention

The present invention relates to a method of manufacturing a semiconductor device, more particularly, to a method of successively depositing a multi-film in a plasma chemical vapor deposition system.

2. Description of Related Art

Chemical vapor deposition (CVD) Process is a technology that deposits films by the chemical reactions between reaction gases that are brought into a high temperature reaction chamber. The CVD process is a commonly adopted deposition method among many semiconductor manufacturing processes. The CVD Process includes low pressure chemical vapor deposition (LPCVD), atmospheric pressure chemical vapor deposition (APCVD), plasma enhanced chemical vapor deposition (PECVD) and high density plasma chemical vapor deposition (HDPCVD) among which PECVD and HDPCVD are most prevalently adopted because of low temperature during the manufacturing processes.

In successively depositing a multi-film by using the CVD process, the needed stacked film is obtained by introducing different reaction gases into a reaction chamber to perform chemical reaction. Nevertheless, in depositing a multi-film by using the plasma CVD process, because static electrics is adsorbed to the wafer, the electric charges in process will cause the next film to have Radio Frequency (RF) delay and overly high reflective power during deposition, resulting in poor quality of the deposited film. On the other hand, the wafer is likely to accumulate too many electric charges and breaks when the wafer is pined up after the film deposition is completed.

### SUMMARY OF THE INVENTION

The present invention is to provide a method of a plasma CVD process to successively deposit a multi-film so that the electric charges accumulated on the substrate are reduced.

The present invention is to provide a method of a plasma CVD process to successively deposit a multi-film so that the quality of the deposited film is enhanced.

Another purpose of the present invention is to provide a method of a plasma CVD process to prevent the wafer from breaking after wafer is pinned up when the deposition process is completed.

The present invention is to provide a method of a plasma chemical vapor deposition system to successively deposit a multi-film. The method includes performing the first plasma deposition process in the chemical vapor deposition system to form a first film on the substrate, performing the second plasma deposition process to form a second film on the first film, and removing electric charges. The step of removing the electric charges includes introducing an inert gas and pumping out the inert gas.

According to the embodiment of the present invention, in the method of the plasma chemical vapor deposition system to successively deposit the multi-film, the inert gas is selected from a group consisting of inert gases, nitrogen, oxygen, carbon dioxide, ammonia, nitrous oxide and the combination thereof.

According the embodiment of the present invention, in the method of the plasma chemical vapor deposition system to successively deposit the multi-film, the inert gas is introduced at a flow rate of 10-1000 sccm for a period of 1-10 seconds.

According to the embodiment of the present invention, the method of the plasma chemical vapor deposition system to successively deposit the multi-film further comprises igniting the plasma after the inert gas is introduced and before the inert gas is pumped out for a period of time; and then turning off the plasma. The power to ignite the plasma is 10-200 watt.

According to the embodiment of the present invention, the method of the aforesaid plasma chemical vapor deposition system to successively deposit the multi-film further comprises pumping out the gas in the chemical vapor deposition system before the inert gas is introduced.

According to the embodiment of the present invention, in the method of the plasma chemical vapor deposition system to successively deposit the multi-film, the step of removing the electric charges is performed between the first and second films being formed, and/or after the second film is formed.

According the embodiment of the present invention, in the method of the plasma chemical vapor deposition system to successively deposit the multi-film, the second film is the last film of the multi-film.

According to the embodiment of the present invention, in the method of the plasma chemical vapor deposition system to successively deposit the multi-film, either the first film or the second film contains a nitride film; and the step of removing the electric charges is performed after the nitride film is formed.

According to the embodiment of the present invention, in the method of the plasma chemical vapor deposition system to successively deposit the multi-film, the first film/the second film include a silicon oxide layer/an inorganic anti-reflection coating, a silicon nitride layer/an inorganic anti-reflection coating, a barrier layer/a low dielectric constant material layer, a silicon nitride layer/a silicon oxide interlayer dielectric layer or a silicon-oxy-nitride layer/a silicon oxide interlayer dielectric layer.

According to the embodiment of the present invention, in the method of the s plasma chemical vapor deposition system to successively deposit the multi-film, the material for the barrier layer is selected from a group consisting of silicon nitride, silicon-oxy-nitride (SiON), silicon carbide (SiC), silicon oxycarbide (SiCO), silicon carbide nitride (SiCN), silicon carboxynitride (SiCNO) and the combination thereof.

According the embodiment of the present invention, the method of the plasma chemical vapor deposition system to successively deposit the multi-film further comprises forming a third film on the substrate after the second film is formed.

According the embodiment of the present invention, the method of the plasma chemical vapor deposition system to successively deposit the multi-film further comprises removing the electric charges after the third film is formed.

According the embodiment of the present invention, in the method of the plasma chemical vapor deposition system to successively deposit the multi-film, the first film/the second film/the third film include a silicon oxide layer/a silicon nitride layer/a silicon oxide layer.

The present invention provides a method of removing the electric charges accumulated on the substrate in a system after a plasma process. The method includes introducing an inert gas into the system and pumping out the inert gas.

According to the embodiment of the present invention, in the method of removing the electric charges accumulated on the substrate in the system after the plasma process, the inert gas is selected from a group consisting of inert gases, nitrogen, oxygen, carbon dioxide, ammonia, nitrous oxide and the combination thereof.

According to the embodiment of the present invention, in the method of removing the electric charges accumulated on the substrate in the system after the plasma process, the inert gas is introduced at a flow rate of 10-1000 sccm for a period of 1-10 seconds.

According to the embodiment of the present invention, the method of removing the electric charges accumulated on the substrate after the plasma process in the system, further comprises igniting a plasma after the inert gas is introduced the system and before the inert gas is pumped out, and turning off the plasma. The power to ignite the plasma is 10-200 watt.

According to the embodiment of the present invention, the method of removing the electric charges accumulated on the substrate in the system further comprises pumping out the gas from the system before the inert gas is introduced into the system.

In the present invention, the method of successively depositing the multi-film can reduce the electric charges to accumulate on the substrate and enhance the quality of the deposited film, preventing the wafer from breaking when the wafer is pined up after the deposition process.

In order to the make the aforementioned and other objects, features and advantages of the present invention comprehensible, a preferred embodiment accompanied with figures are described in detail below.

### BRIEF DESCRIPTION OF THE DRAWINGS

FIG. 1 is a flow diagram showing a method of a plasma CVD system to successively deposit a multi-film, according to one embodiment of the present invention.

FIG. 1A is a flow diagram showing a step of removing the electric charges, according to one embodiment of the present invention.

FIG. 1B is a flow diagram showing another step of removing the electric charges, according to one embodiment of the present invention.

FIG. 1C is a flow diagram showing another step of removing the electric charges, according to one embodiment of the present invention.

FIG. 2 is a schematic cross-sectional view showing a substrate having a double-stacked film thereon, according to one embodiment of the present invention.

FIG. 3 is a schematic cross-sectional view showing dual damascene process by using a double-stacked film, according to one embodiment of the present invention.

FIG. 4 is a schematic cross-sectional view showing a contact process by using a double-stacked film, according to one embodiment of the present invention.

FIG. 5 is a schematic cross-sectional view showing a protection layer by using the double-stacked film, according to one embodiment of the present invention.

FIG. 6 is a flow diagram showing a method of a plasma CVD system to successively deposit three-stacked film, according to one embodiment of the present invention.

FIG. 7 is a schematic cross-sectional view showing a substrate having a three-stacked film, according to one embodiment of the present invention.

### DESCRIPTION OF EMBODIMENTS

The method of depositing the multi-film according to the present invention is to perform a step of removing the electric charges after the deposition of the last film and/or between the two adjacent film deposition processes, so that the electric charges accumulated on the substrate are removed and thereby reduced. Details are illustrated below.

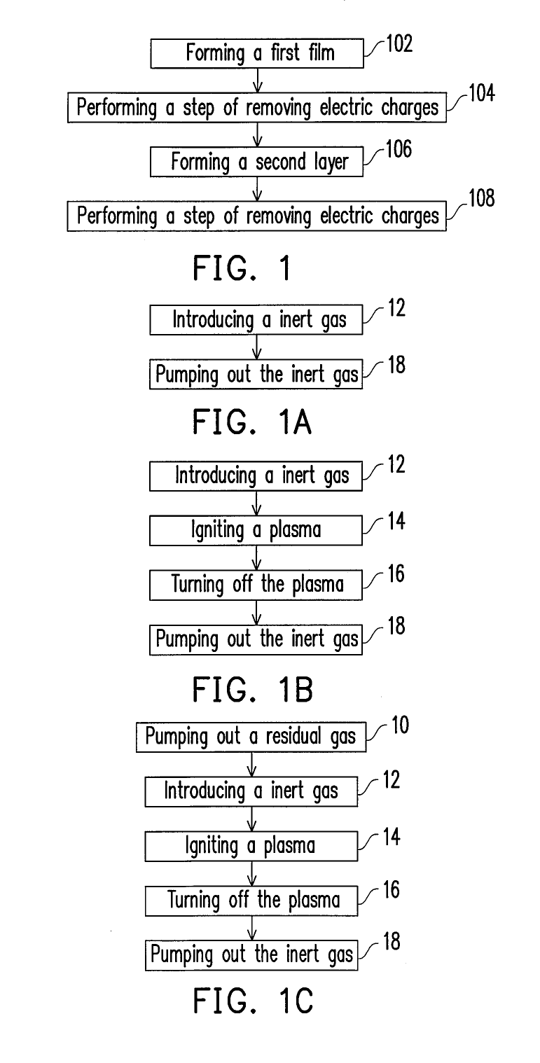

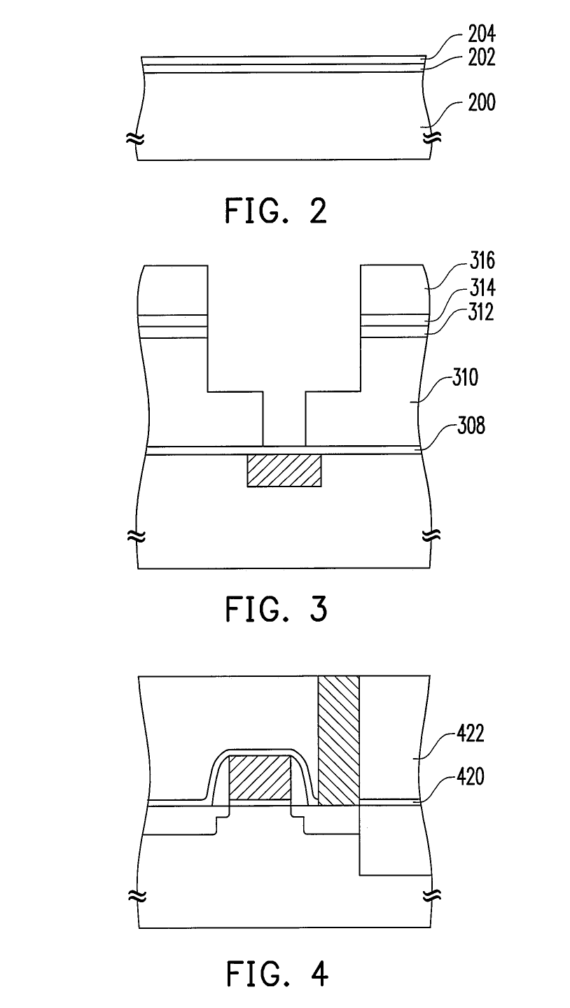

FIG. 1 is a flow diagram showing a method of a plasma chemical vapor deposition system to successively deposit double-stacked film, according to one embodiment of the present invention. FIG. 2 is a schematic cross-sectional view showing a substrate having a double-stacked film, according to one embodiment of the present invention.

Referring to FIGS. 1 and 2, Step 102 is performed by forming a first film 202 on a substrate 200. The method of the process is to introduce reaction gas and carrier gas to the reaction chamber of the Plasma Enhanced chemical vapor deposition system or the High Density Plasma Deposition System. After the pressure is steady, the plasma deposition process is performed by igniting the plasma so that a first film 202 is formed on substrate 200. Then, the plasma is turned off.

Referring to FIGS. 1 and 2, Step 104, is performed by removing the electric charges accumulated on the substrate 200. Referring to 1A, in one embodiment of the present invention, the step of remove the electric charges includes introducing an inert gas into the reaction chamber of the system for a while as indicated by Step 12 and pumping the inert gas out of the reaction chamber as indicated by Step 18. The temperature in the reaction chamber is from about 350° C. to 450° C. The inert gas is selected from a group consisting of inert gases, nitrogen, oxygen, carbon dioxide, armmonia, nitrous oxide and the combination thereof. The inert gas is such as hydrogen, helium and neon. The inert gas is introduced at a flow rate of about 10-1000 sccm for a period of about 1-10 seconds. Referring to FIG. 1B, in another embodiment of the present invention, the step of removing the electric charges can be performed by introducing inert gas into the system's chamber as indicated by Step 12. The next is to ignite the plasma for a period of time as indicated by Step 14. Afterward, the plasma is turned off as indicated by Step 16; and then the inert gas is pumped out the reaction chamber of the system as indicated in Step 18. The power to ignite the plasma is preferably about 5-1000 watt, more preferably about 10-200 watt. Referring to FIG. 1C, in another embodiment of the present invention, the step of removing the electric charges is to pump out the remaining gas first from the reaction chamber as indicated by Step 10. Then, inert gas is introduced into the system as indicated by Step 12. Next, the plasma is ignited for a period of time as indicated by Step 14. Afterward, the plasma is turned off as indicated by Step 16; then, the inert gas is pumped out as indicated in Step 18. The power to ignite the plasma is preferably about 5-1000 watt, more preferably about 10-200 watt. The plasma is ignited for about 1-10 seconds.

Step 106 is performed by forming a second film 204 on substrate 200. The process is performed by introducing reaction gas and carrier gas into the reaction chamber. When the pressure is steady, following igniting the plasma, another plasma deposition process is performed to form a second film on the substrate. Afterward, the plasma is turned off.

Referring to Step 108, the step of removing the electric charges accumulated on substrate 200 is performed again. In one embodiment of the present invention, the step of removing the electric charges includes introducing inert gas into the reaction chamber of the system for a while and pumping the inert gas out of the reaction chamber. The temperature in the reaction chamber is from about 350° C. to 450° C. The inert gas is selected from a group consisting of inert gases, nitrogen, oxygen, carbon dioxide, armmonia, nitrous oxide and the combination thereof. The inert gas is such as hydrogen, helium and neon. The inert gas is introduced at a flow rate of about 10-1000 sccm for a period of about 1-10 seconds. In another embodiment of the present invention, the step of removing the electric charges can be performed by introducing inert gas into the reaction chamber of the system; then igniting the plasma for a period of time. After that the plasma is turned off and the inert gas is pumped out of the reaction chamber of the system. The power of the plasma is preferably about 5-1000 watt, more preferably about 10-200 watt. In another embodiment of the present invention, the step of removing the electric charges is to pump out remaining gas from the reaction chamber first; then bring an inert gas into the reaction chamber. Afterward, the plasma is ignited for a period of time. Afterward, the plasma is turned off and the inert gas is pumped out. The power to ignite the plasma is preferably about 5-1000 watt, more preferably about 10-200 watt. The plasma is ignited for a period of about 1-10 seconds.

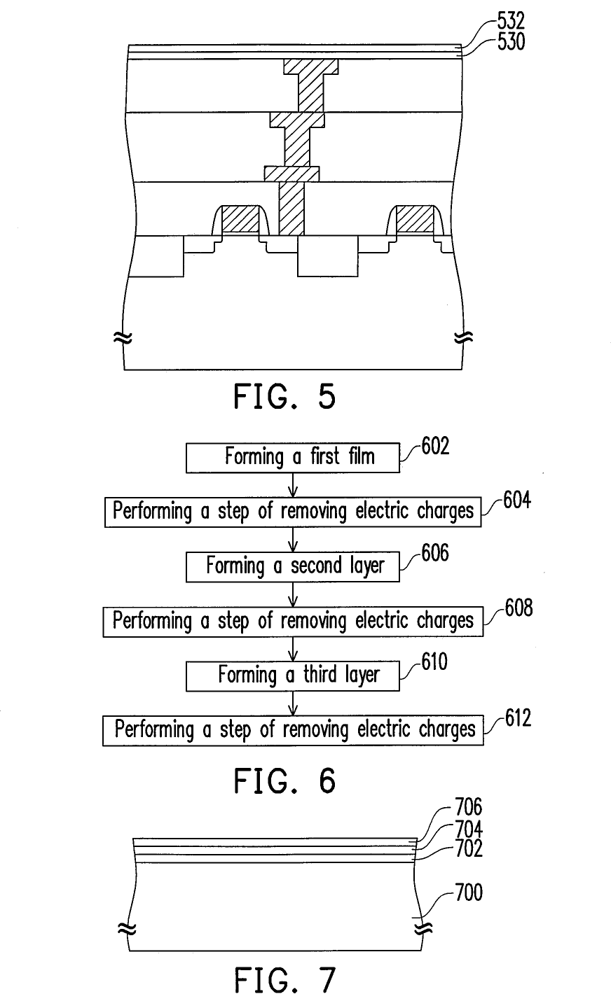

In one embodiment of successively depositing dual films according to the present invention, the first film 202 and the second film 204 on substrate 200 are. used as a dual hard mask of a silicon oxide layer and an inorganic anti-reflection coating, or a silicon nitride layer and an inorganic anti-reflection coating. Referring to FIG. 3, the aforesaid first film 202 and the second film 204, for instance, are a dual hard mask formed above dielectric layer 310 and below photoresist layer 316 in dual damascene process and constituted by silicon oxide layer 312 and inorganic anti-reflection coating (DARC) 314, or silicon nitride layer 312 and inorganic anti-reflection coating 314. Referring to FIG. 3, in another embodiment of the present invention, the first layer 202 and the second layer 204, for instance, are barrier layer 308 and low dielectric constant material layer 310 in dual damascene process. The material of the barrier layer 308 is selected from a group consisting of silicon nitride, silicon-oxy-nitride (SiON), silicon carbide (SiC), silicon oxycarbide (SiCO), silicon carbide nitride (SiCN), silicon carboxynitride (SiCNO) and the combination thereof. The material of the low dielectric constant layer 310 is, for instance, FSG and Parylene. Referring to FIG. 4, in another embodiment of the present invention, the first layer 202 and the second layer 204 are, for instance, silicon nitride etching stop layer 420 and silicon oxide inter-layer dielectric layer (ILD) 422, or silicon-oxy-nitride etching stop layer 420 and silicon oxide inter-layer dielectric layer 422 in contact process. Referring to FIG. 5, in another embodiment of the present invention, the first layer 202 and the second layer 204 are, for instance, silicon oxide layer 530 and silicon nitride layer 532 serving as a protection layer covering the substrate after mental lines are formed.

According to the aforesaid multi-film process, the step of removing electric charges is performed every time after each film is deposited. However, practical applications are not limited thereto, it can be adjusted if necessary.

In one embodiment of the present invention, if the electric charges remaining on the substrate in the first film deposition process does not affect the second film deposition process to cause radio frequency delay and overly high reflective power and result in the poor quality of the deposited films, the step of removing the electric charges before performing second film deposition process is not needed. The step of removing the electric charges can be performed only after the second film is deposited.

FIG. 6 is a flow diagram showing a method of a plasma chemical vapor deposition system to successively deposit three-stacked film, according to one embodiment of the present invention. FIG. 7 is a schematic cross-sectional view showing a substrate having a three-stacked film.

Referring to Step 602 of FIGS. 6 and 7, in the reaction chamber of a plasma chemical vapor deposition system, such as a plasma enhanced chemical vapor deposition system or a high-density plasma deposition system, reaction gas and carrier gas are introduced into the reaction chamber When the pressure is steady, the plasma deposition process is performed by igniting the plasma so that a first film 702 is formed on substrate 700. Then, the plasma is turned off.

Step 604 is performed by removing electric charges accumulated on the substrate 700. In one embodiment of the present invention, the step of removing the electric charges includes introducing inert gas into the reaction chamber of the system for a while and pumping the inert gas out of the reaction chamber. The temperature in the reaction chamber is from about 350° C. to 450° C. The inert gas is selected from a group consisting of inert gases, nitrogen, oxygen, carbon dioxide, armmonia, nitrous oxide and the combination thereof. The inert gas is such as hydrogen, helium and neon. The inert gas is introduced at a flow rate of about 10-1000 sccm for a period of about 1-10 seconds. In another embodiment of the present invention, the step of removing the electric charges can be performed by introducing inert gas into the reaction chamber of the system; then igniting the plasma for a period of time. After that the plasma is turned off and the inert gas is pumped out of the reaction chamber of the system. The power of the plasma is preferably about 5-1000 watt, more preferably about 10-200 watt. In another embodiment of the present invention, the step of removing the electric charges is to pump out remaining gas from the reaction chamber first; then bring an inert gas into the reaction chamber. Afterward, the plasma is ignited for a period of time. Afterward, the plasma is turned off and the inert gas is pumped out the reaction chamber. The power to ignite the plasma is preferably about 5-1000 watt, more-preferably about 10-200 watt. The plasma is ignited for a period of about 1-10 seconds.

Step 606 is performed by introducing reaction gas and carrier gas into the reaction chamber. When the pressure is steady, g the plasma is ignited, another plasma deposition process is performed to form a second film 704 on the substrate 700. Afterward, the plasma is turned off.

Step 608 is performed by once again removing the electric charges accumulated on the substrate 700. In one embodiment of the present invention, the step of removing the electric charges includes introducing inert gas into the reaction chamber of the system for a while and pumping the inert gas out of the reaction chamber. The temperature in the reaction chamber is from about 350° C. to 450° C. The inert gas is selected from a group consisting of inert gases, nitrogen, oxygen, carbon dioxide, armmonia, nitrous oxide and the combination thereof. The inert gas is such as hydrogen, helium and neon. The inert gas is introduced at a flow rate of about 10-1000 sccm for a period of about 1-10 seconds. In another embodiment of the present invention, the step of removing the electric charges can be performed by introducing inert gas into the reaction chamber of the system; then igniting the plasma for a period of time. After that the plasma is turned off and the inert gas is pumped out of the reaction chamber of the system. The power of the plasma is preferably about 5-1000 watt, more preferably about 10-200 watt. In another embodiment of the present invention, the step of removing the electric charges is to pump out remaining gas from the reaction chamber first; then bring an inert gas into the reaction chamber. Afterward, the plasma is ignited for a period of time. Afterward, the plasma is turned off and the inert gas is pumped out the reaction chamber. The power to ignite the plasma is preferably about 5-1000 watt, more preferably about 10-200 watt. The plasma is ignited for a period of about 1-10 seconds.

Step 610 is performed by introducing reaction gas and carrier gas into the reaction chamber. When the pressure is steady, the plasma is ignited, another plasma deposition process is performed to form a third film 706 on the substrate 700. Afterward, the plasma is turned off.

Step 612 is performed by once again removing the electric charges accumulated on the substrate 700. In one embodiment of the present invention, the step of removing the electric charges includes introducing inert gas into the reaction chamber of the system for a while and pumping the inert gas out of the reaction chamber. The temperature in the reaction chamber is from about 350° C. to 450° C. The inert gas is selected from a group consisting of inert gases, nitrogen, oxygen, carbon dioxide, armmonia, nitrous oxide and the combination thereof. The inert gas is such as hydrogen, helium and neon. The inert gas is introduced at a flow rate of about 10-1000 sccm for a period of about 1-10 seconds. In another embodiment of the present invention, the step of removing the electric charges can be performed by introducing inert gas into the reaction chamber of the system; then igniting the plasma for a period of time. After that the plasma is turned off and the inert gas is pumped out of the reaction chamber of the system. The power of the plasma is preferably about 5-1000 watt, more preferably about 10-200 watt. In another embodiment of the present invention, the step of removing the electric charges is to pump out remaining gas from the reaction chamber first; then bring an inert gas into the reaction chamber. Afterward, the plasma is ignited for a period of time. Afterward, the plasma is turned off and the inert gas is pumped out the reaction chamber. The power to ignite the plasma is preferably about 5-1000 watt, more preferably about 10-200 watt. The plasma is ignited for a period of about 1-10 seconds.

If the multi-film has more layers, Steps 610 and 612 can be performed repeatedly.

Referring to FIG. 7, in one embodiment of successively depositing a dual film according to the present invention, the first film 702, the second film 704 and the third film 706, deposed on the substrate 700, are a stacked layer of O₁/N/O₂, which is used as a charge storage layer of a silicon nitride nonvolatile memory device or a inter-polysilicon dielectric of flash memory device.

According to the aforesaid multi-film process, the step of removing the electric charges is performed every time after each film is deposited. However, practical applications are not limited thereto, it can be adjusted if necessary.

In one embodiment of the present invention, if the electric charges remaining on the substrate in the first film deposition process does not affect the second film deposition process to cause radio frequency delay and overly high reflective power and result in the poor quality of the deposited films, the step of removing the electric charges before performing second film deposition process is not needed. For example, in depositing silicon oxide/silicon nitride/silicon oxide (O₁/N/O₂), after the silicon oxide layer (O₁) is deposited and if the next layer silicon nitride is being deposited without being affected so the quality of the films remain the same, the step of removing the electric charges is not needed before the silicon nitride layer is formed. On the other hand, if the deposited silicon nitride layer will affect the next silicon oxide layer (O₂), the step of removing the electric charges can be performed before the silicon oxide layer (O₂) is formed to improve the silicon oxide layer's quality. According to many relevant experiments, in depositing a multi-film having a nitride film, such as a silicon nitride layer, the quality of the next deposited layer is usually affected after the nitride layer is deposited. It likely relates to that the reaction gas includes ammonia in the process for depositing a silicon nitride layer, and ammonia is changed to nitrogen radical after plasma is ignited.

In one embodiment of the present invention, in depositing each layer, if the quality of the next deposited layer is not affected by the deposition process of the previous layer, the step of removing the electric charges is not needed between the deposition processes of two layers. The step of removing the electric charges is only needed after the last film deposition is completed so that the electric charges can be removed from the substrate to prevent it from breaking due to the wafer is pinned up in the end of film deposition.

To sum up, the method of successively depositing multi films according to the present invention can reduce electric charges to accumulate on the substrate, enhance the quality of the deposited films and prevent the wafer from breaking upon being taken out after the deposition process is all completed.

What is claimed is:

1. A method of a plasma chemical vapor deposition system to successively deposit a multi-film, comprising:
performing a first plasma deposition process on the chemical vapor deposition system to form a first film on a substrate;
performing a second plasma deposition process to form a second film on the first film; and
performing a step of removing electric charges, comprising:
introducing an inert gas; and
pumping out the inert gas.

2. The method of claim 1, wherein the inert gas is selected from a group consisting of inert gases, nitrogen, oxygen, carbon dioxide, ammonia, nitrous oxide and the combination thereof.

3. The method of claim 1, wherein a flow rate of the inert gas is about 10-1000 sccm.

4. The method of claim 1 further comprising:
igniting a plasma after the inert gas is introduced and before the gas is pumped out, and
turning off the plasma.

5. The method of claim 4, wherein the power to ignite the plasma is about 5-1000 watt

6. The method of claim 5, wherein the power to ignite the plasma is about 10-200 watt.

7. The method of claim 4, wherein the time for igniting the plasma is ignited for a period of about 1-10 seconds.

8. The method of claim 4, further comprising pumping out the gas from the system before the step of introducing the inert gas.

9. The method of claim 1, wherein the step of removing the electric charges is performed between the step of forming the first and second films, and/or after the step of forming the second film.

10. The method of claim 9, wherein the second film is the last layer of the multi-film.

11. The method of claim 9, wherein either the first film or the second film contains a nitride film and the step of removing the electric charges is performed after the nitride film is formed.

12. The method of claim 9, wherein the first film/the second film comprise a silicon oxide layer/an inorganic anti-reflection coating, a silicon nitride layer/an inorganic anti-reflection coating, a barrier layer/a low dielectric constant material layer, a silicon nitride layer/a silicon oxide interlayer dielectric or a silicon-oxy-nitride layer/a silicon oxide interlayer dielectric layer.

13. The method of claim 12, wherein the material of the barrier layer is selected from a group consisting of silicon nitride, silicon-oxy-nitride (SiON), silicon carbide (SiC), silicon oxycarbide (SiCO), silicon carbide nitride (SiCN), silicon carboxynitride (SiCNO) and the combination thereof.

14. The method of claim 9 further comprising forming a third film on the substrate after the second film is formed.

15. The method of claim 14 further comprising performing another step of removing the electric charges after the third film is formed.

16. The method of claim 14, wherein the first film/the second film/the third film include a silicon oxide layer/a silicon nitride layer/a silicon oxide layer.

17. A method of removing electric charges accumulated on the substrate in a system after a plasma process, comprising:
introducing an inert gas into the system; and
pumping out the inert gas.

18. The method claim 17, wherein the inert gas is selected from a group consisting of inert gases, nitrogen, oxygen, carbon dioxide, ammonia, nitrous oxide and the combination thereof.

19. The method of claim 17, wherein a flow rate of the inert gas is about 10-1000 sccm.

20. The method of claim 17 further comprising:
igniting a plasma after the inert gas is introduced and before the gas is pumped out; and
turning off the plasma.

21. The method of claim 20, wherein the power of the plasma is about 5-1000 watt.

22. The method of claim 21, wherein the power of the plasma is about 10-200 watt.

23. The method of claim 21, wherein the plasma is ignited for a period of about 1-10 seconds.

24. The method of claim 17 further comprising pumping out a gas from the system before the inert gas is introduced.
